(19) United States
(12) Patent Application Publication
(10) Pub. No.: US 2026/0169395 A1
(43) Pub. Date: Jun. 18, 2026

(54) ACTUATOR ARRAY, SUBSTRATE TABLE AND LITHOGRAPHIC TOOL

(71) Applicant: ASML Netherlands B.V., Veldhoven (NL)

(72) Inventors: Hans BUTLER, Best (NL); Michael Marinus Anna STEUR, Eindhoven (NL); Bas JANSEN, Rosmalen (NL); Jeroen VAN DUIVENBODE, Veldhoven (NL); Andrea DEGASPERI, Eindhoven (NL)

(73) Assignee: ASML Netherlands B.V., Veldhoven (NL)

(21) Appl. No.: 19/128,615

(22) PCT Filed: Nov. 23, 2023
(86) PCT No.: PCT/EP2023/082790

§ 371 Date: May 9, 2025

(30) Foreign Application Priority Data
Dec. 1, 2022 (EP) 22210952.2
Mar. 3, 2023 (EP) 23160035.4

(51) Int. Cl. G03F 7/00; H02M 3/156; H02M 3/158

(52) U.S. Cl. CPC G03F 7/707; G03F 7/70633; H02M 3/156; H02M 3/158

(57) ABSTRACT

An actuator array, comprising multiple actuator cells, each actuator cell comprising at least one piezo electric actuator, a reference capacitor, in a series connection with the piezo electric actuator, a switch assembly configured to switch power to the at least one actuator, a control circuit connected to the switch assembly and configured to control the switch assembly and comprising a serial control input, a feedback line configured to provide a reference capacitor voltage representative of a voltage across the reference capacitor to the control circuit, wherein the piezo electric actuator and the reference capacitor are arranged at a first location and the control circuit is arranged at a second location, a power line connected to at least the switch assembly of each actuator cell for powering at least the switch assembly of each actuator cell.

### CROSS-REFERENCE TO RELATED APPLICATIONS

The application claims priority of EP application 22210952.2 which was filed on 1 Dec. 2022 and EP application 23160035.4 which was filed on 3 Mar. 2023, and which are incorporated herein in their entirety by reference.

### FIELD

The present invention relates to an actuator array, a substrate table comprising such an actuator array, and a lithographic tool.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

The lithographic apparatus may comprise a substrate table to support the substrate. The substrate table may comprise a substrate holding surface, which may for example be formed by top surfaces of a plurality of burls. As the substrate may thereby be supported by the top surfaces of the plurality of burls, a contacting surface between the substrate on the one hand and the substrate table on the other hand may be small. The substrate table may comprise a plurality of actuators, to move the burls, or a subset of the burls, e.g. in a vertical direction, for example to be able to lift the substrate or to be able to compensate for any unflattness of the substrate. The actuators may for example comprise piezo electric actuators. The actuators may be individually controllable, for example to be able to take account of an unflatness of the substrate or to be able to lift the substrate in a certain order: for example, the centre burls may be lifted first, to hold the substrate, after which more peripheral burls are actuated to lift, enabling to e.g. contact the substrate in a defined manner.

Using a large number of burls and a correspondingly large number of actuators, driving the actuators may involve a large number of electrical conductors (e.g. wires). to the substrate table. The wires may on the one hand hamper an ability of the substrate table to move, accelerate, etc, and on the other hand may transfer forces, vibrations or other disturbances onto the substrate table.

Multiplexing may provide some improvement as a number of wires may be reduced. For example, by means of having a single high-voltage line per multiplex, and low-voltage signals for addressing individual cells, a number of connections may be reduced. For a large array of cells however having e.g. hundredths or thousands of actuators, the number of connections may still be significant. Also, the larger the multiplex, the longer it takes to update each cell, as the multiplex may address each cell one at a time. Therefore, hold capacitors or other buffers have to be significant in capacitance and size (which again may requiring longer addressing to fully charge) to keep e.g. a desired potential over the addressing cycle.

Requirements on lithographic apparatusses tend to be raised over time. Larger substrates are to be processed, which may require a size of the substrate table to be increased. Furthermore, substrate processing times are to be decreased, which may translate into increased velocity and acceleration of the substrate table. Still further, accuracy may be increased, enabling to project patterns on the substrate with a smaller line width.

### SUMMARY

Considering the above, it is an object of the invention to provide a substrate table that facilitates a raise of requirement specifications on the lithographic apparatus.

According to an aspect of the invention, there is provided an actuator array, comprising:
multiple actuator cells, each actuator cell comprising
at least one piezo electric actuator,
a reference capacitor, in a series connection with the piezo electric actuator,
a switch assembly configured to switch power to the at least one actuator,
a control circuit connected to the switch assembly and configured to control the switch assembly and comprising a serial control input,
a feedback line configured to provide a reference capacitor voltage representative of a voltage across the reference capacitor to the control circuit,
wherein the piezo electric actuator and the reference capacitor are arranged at a first location and the control circuit is arranged at a second location, wherein the second location is remote from the first location and wherein the feedback line extends between the first location and the second location,
a power line connected to at least the switch assembly of each actuator cell for powering at least the switch assembly of each actuator cell, and
a control line connected to the serial control input of the control circuit of each actuator cell to transmit control data to the control circuit of at least one of the actuator cells.

According to an aspect of the invention, there is provided a substrate table comprising a plurality of burls configured to support a substrate, the substrate table comprising an actuator array according to the invention, wherein the actuators of the actuator array are configured to actuate at least a subset of the burls.

According to an aspect of the invention, there is provided a lithographic tool comprising the substrate table according to the invention. According to a still further aspect of the invention, there is provided a lithographic tool comprising the actuator array according to the invention.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus according to an embodiment of the invention;

FIG. 2 depicts a detailed view of a part of the lithographic apparatus of FIG. 1;

FIG. 3 schematically depicts a position control system as part of a positioning system according to an embodiment of the invention;

FIG. 4 schematically depicts a part of an actuator array according to an embodiment of the invention;

FIG. 5 schematically depicts a part of an actuator array according to another embodiment of the invention;

FIG. 6 schematically depicts a part of an actuator array according to yet another embodiment of the invention;

FIG. 7 depicts a top view of piezo electric layer comprising a plurality of actuators as may be employed in embodiments of the invention;

FIG. 8 schematically depicts a side view of a part of an actuator array according to yet another embodiment of the invention;

FIG. 9 schematically depicts an actuator cell;

FIG. 10 schematically depicts an actuator cell according to an embodiment of the invention;

FIG. 11 schematically depicts an actuator cell according to another embodiment of the invention; and

FIG. 12 schematically depicts a part of an actuator array according to a further embodiment of the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

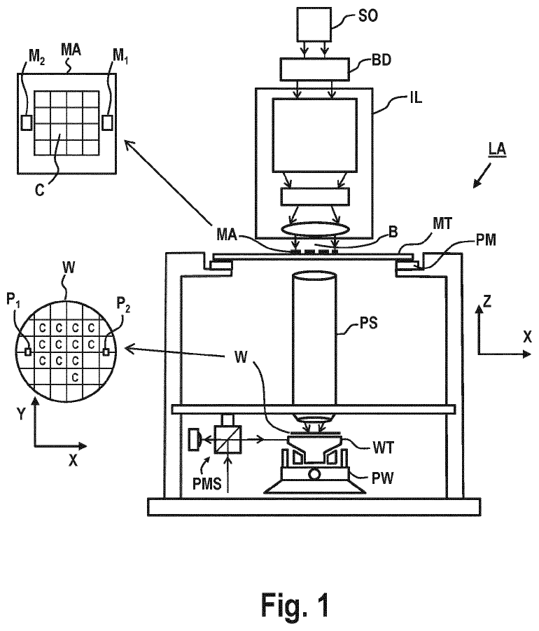

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the patterning device MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

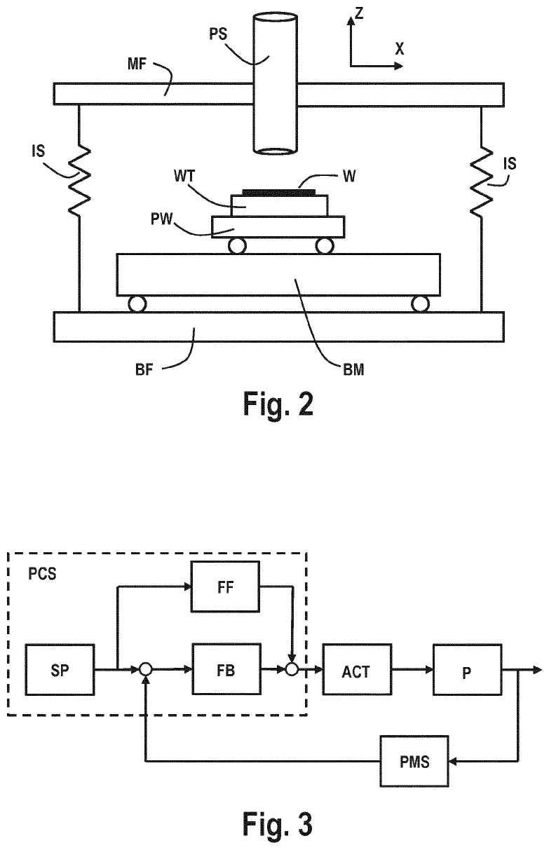

FIG. 2 shows a more detailed view of a part of the lithographic apparatus LA of FIG. 1. The lithographic apparatus LA may be provided with a base frame BF, a balance mass BM, a metrology frame MF and a vibration isolation system IS. The metrology frame MF supports the projection system PS. Additionally, the metrology frame MF may support a part of the position measurement system PMS. The metrology frame MF is supported by the base frame BF via the vibration isolation system IS. The vibration isolation system IS is arranged to prevent or reduce vibrations from propagating from the base frame BF to the metrology frame MF.

The second positioner PW is arranged to accelerate the substrate support WT by providing a driving force between the substrate support WT and the balance mass BM. The driving force accelerates the substrate support WT in a desired direction. Due to the conservation of momentum, the driving force is also applied to the balance mass BM with equal magnitude, but at a direction opposite to the desired direction. Typically, the mass of the balance mass BM is significantly larger than the masses of the moving part of the second positioner PW and the substrate support WT.

In an embodiment, the second positioner PW is supported by the balance mass BM. For example, wherein the second positioner PW comprises a planar motor to levitate the substrate support WT above the balance mass BM. In another embodiment, the second positioner PW is supported by the base frame BF. For example, wherein the second positioner PW comprises a linear motor and wherein the second positioner PW comprises a bearing, like a gas bearing, to levitate the substrate support WT above the base frame BF.

The position measurement system PMS may comprise any type of sensor that is suitable to determine a position of the substrate support WT. The position measurement system PMS may comprise any type of sensor that is suitable to determine a position of the mask support MT. The sensor may be an optical sensor such as an interferometer or an encoder. The position measurement system PMS may comprise a combined system of an interferometer and an encoder. The sensor may be another type of sensor, such as a magnetic sensor, a capacitive sensor or an inductive sensor. The position measurement system PMS may determine the position relative to a reference, for example the metrology frame MF or the projection system PS. The position measurement system PMS may determine the position of the substrate table WT and/or the mask support MT by measuring the position or by measuring a time derivative of the position, such as velocity or acceleration.

The position measurement system PMS may comprise an encoder system. An encoder system is known from for example, United States patent application US2007/0058173A1, filed on Sep. 7, 2006, hereby incorporated by reference. The encoder system comprises an encoder head, a grating and a sensor. The encoder system may receive a primary radiation beam and a secondary radiation beam. Both the primary radiation beam as well as the secondary radiation beam originate from the same radiation beam, i.e., the original radiation beam. At least one of the primary radiation beam and the secondary radiation beam is created by diffracting the original radiation beam with the grating. If both the primary radiation beam and the secondary radiation beam are created by diffracting the original radiation beam with the grating, the primary radiation beam needs to have a different diffraction order than the secondary radiation beam. Different diffraction orders are, for example, +1^{st} order, −1^{st} order, +2^{nd} order and −2^{nd} order. The encoder system optically combines the primary radiation beam and the secondary radiation beam into a combined radiation beam. A sensor in the encoder head determines a phase or phase difference of the combined radiation beam. The sensor generates a signal based on the phase or phase difference. The signal is representative of a position of the encoder head relative to the grating. One of the encoder head and the grating may be arranged on the substrate structure WT. The other of the encoder head and the grating may be arranged on the metrology frame MF or the base frame BF. For example, a plurality of encoder heads is arranged on the metrology frame MF, whereas a grating is arranged on a top surface of the substrate support WT. In another example, a grating is arranged on a bottom surface of the substrate support WT, and an encoder head is arranged below the substrate support WT.

The position measurement system PMS may comprise an interferometer system. An interferometer system is known from, for example, U.S. Pat. No. 6,020,964, filed on Jul. 13, 1998, hereby incorporated by reference. The interferometer system may comprise a beam splitter, a mirror, a reference mirror and a sensor. A beam of radiation is split by the beam splitter into a reference beam and a measurement beam. The measurement beam propagates to the mirror and is reflected by the mirror back to the beam splitter. The reference beam propagates to the reference mirror and is reflected by the reference mirror back to the beam splitter. At the beam splitter, the measurement beam and the reference beam are combined into a combined radiation beam. The combined radiation beam is incident on the sensor. The sensor determines a phase or a frequency of the combined radiation beam. The sensor generates a signal based on the phase or the frequency. The signal is representative of a displacement of the mirror. In an embodiment, the mirror is connected to the substrate support WT. The reference mirror may be connected to the metrology frame MF. In an embodiment, the measurement beam and the reference beam are combined into a combined radiation beam by an additional optical component instead of the beam splitter.

The first positioner PM may comprise a long-stroke module and a short-stroke module. The short-stroke module is arranged to move the mask support MT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the first positioner PM is able to move the mask support MT relative to the projection system PS with a high accuracy over a large range of movement. Similarly, the second positioner PW may comprise a long-stroke module and a short-stroke module. The short-stroke module is arranged to move the substrate support WT relative to the long-stroke module with a high accuracy over a small range of movement. The long-stroke module is arranged to move the short-stroke module relative to the projection system PS with a relatively low accuracy over a large range of movement. With the combination of the long-stroke module and the short-stroke module, the second positioner PW is able to move the substrate support WT relative to the projection system PS with a high accuracy over a large range of movement.

The first positioner PM and the second positioner PW each are provided with an actuator to move respectively the mask support MT and the substrate support WT. The actuator may be a linear actuator to provide a driving force along a single axis, for example the y-axis. Multiple linear actuators may be applied to provide driving forces along multiple axis. The actuator may be a planar actuator to provide a driving force along multiple axis. For example, the planar actuator may be arranged to move the substrate support WT in 6 degrees of freedom. The actuator may be an electromagnetic actuator comprising at least one coil and at least one magnet. The actuator is arranged to move the at least one coil relative to the at least one magnet by applying an electrical current to the at least one coil. The actuator may be a moving-magnet type actuator, which has the at least one magnet coupled to the substrate support WT respectively to the mask support MT. The actuator may be a moving-coil type actuator which has the at least one coil coupled to the substrate support WT respectively to the mask support MT. The actuator may be a voice-coil actuator, a reluctance actuator, a Lorentz-actuator or a piezo-actuator, or any other suitable actuator.

The lithographic apparatus LA comprises a position control system PCS as schematically depicted in FIG. 3. The position control system PCS comprises a setpoint generator SP, a feedforward controller FF and a feedback controller FB. The position control system PCS provides a drive signal to the actuator ACT. The actuator ACT may be the actuator of the first positioner PM or the second positioner PW. The actuator ACT drives the plant P, which may comprise the substrate support WT or the mask support MT. An output of the plant P is a position quantity such as position or velocity or acceleration. The position quantity is measured with the position measurement system PMS. The position measurement system PMS generates a signal, which is a position signal representative of the position quantity of the plant P. The setpoint generator SP generates a signal, which is a reference signal representative of a desired position quantity of the plant P. For example, the reference signal represents a desired trajectory of the substrate support WT. A difference between the reference signal and the position signal forms an input for the feedback controller FB. Based on the input, the feedback controller FB provides at least part of the drive signal for the actuator ACT. The reference signal may form an input for the feedforward controller FF. Based on the input, the feedforward controller FF provides at least part of the drive signal for the actuator ACT. The feedforward FF may make use of information about dynamical characteristics of the plant P, such as mass, stiffness, resonance modes and eigenfrequencies.

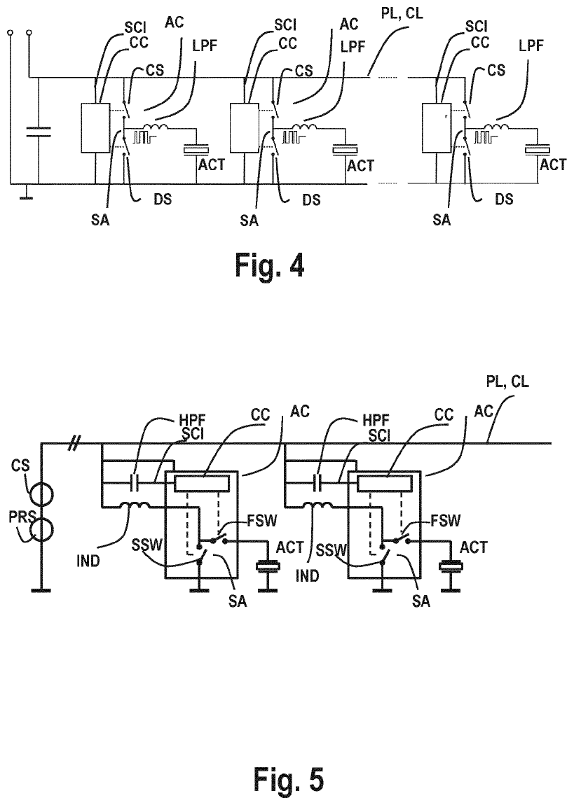

FIG. 4 depicts a schematic view of a part of the actuator array according to an embodiment of the invention. The actuator array comprises a power line PL and a control line CL which are in the present example integral to form a single conductor. The power line provides power to a plurality of actuator cells AC, which each comprise at least one actuator ACT, a switching assembly SA connected to the actuator ACT and to the power line PL in order to provide power from the power line to the actuator, and a control circuit CC. The control circuit CC is connected to the switching assembly in order to control a switching of the switching assembly. The switching assembly comprises a serial control input SCI which is connected to the control line, in the present example being integral with the power line, i.e. the control line and the power line being the same electrical conductor. In the present example, the switch assembly comprises a charging switch CS connected between the power line and a switching assembly output and a discharging switch DS connected between the switching assembly output and ground. The actuator cell further comprises an inductor or other low pass filter LPF which connects the switching assembly output to the actuator. The switches of the switching assembly may comprise controllable switches, such as transistors, e.g. field effect transistors.

The switches of the switching assembly are controlled by the control device. For example, the switches are alternately driven into a conductive state, whereby driving the charging switch into a conductive state provides that the actuator is connected via the inductor to the power line, and driving the discharging switch into a conductive state provides that the actuator is connected via the inductor to ground. Accordingly, the actuator may be alternately charged and discharged. A ripple of the switching may be suppressed or at least reduced by the inductor or other low pass filter. Setting a duty cycle of the switching, i.e. a duty cycle of activating the charging switch and the discharging switch, may enable to set an actuator voltage between a power supply voltage of the power line and ground.

The actuator may for example comprise a piezo electric actuator. Setting the actuator voltage may enable to control an actuation (e.g. a displacement) of the piezo electric actuator. FIG. 4 depicts three of the actuator cells, actuator cell 1, actuator cell 2, actuator cel N. It will be understood that plural actuator cells may be driven, whereby use may be made of a single conductor power line and a single control line, or, as in the preset embodiment, the combined power line and control line.

The power line may provide a power supply voltage to the actuator cells. Control data may be superimposed, e.g. in a form of a high frequency signal. Each actuator cell may for example comprise a high pass filter, such as a capacitor, connected between the power line and the serial control input of the control unit, to filter the DC or low frequency power voltage from the combined power and control on the single line, thus to enable to transmit the serial control data to the control unit of the actuator cell. The control data may be transmitted in a form a serial control data.

Instead of the combined power line and control line, use may be made of separate power and control lines.

Control data may be addressed to one or more of the actuator cells. For example, a respective address may be assigned to each actuator cell. The address may be stored in the control circuit of the actuator cell. For example, each actuator cell is provided with a unique address or groups of actuator cell are provided with the same address. The control data may be transmitted by transmitting via the control line the address of the actuator cell for which the control data is intended, and the control data. For example, the address may be transmitted, and following the address, the control data is transmitted. The transmission may be preceded by e.g. start bits or synchronization bits and may comprise end bits or synchronization bits after transmission of the address and/or the control data. The address may be transmitted as binary data. The control data may be transmitted as binary data. The transmission at the control line is received by all actuator cells, in particular by all control units of the actuator cells. The control unit or control units, of which the address corresponds to the transmitted address, may respond to the transmission by executing the control data. The control data may for example comprise an actuator variable, such as an actuator drive signal magnitude. The control data may for example comprise an actuator drive voltage value or an actuator PWM duty cycle value. The control circuit may, responsive to the control data addressed to it, drive the switching assembly in accordance with the control data. In case plural of the control circuits have been assigned the same address, these control circuits may all respond to the control data addressed to these control circuits, i.e. addressed to these actuator cells.

In an embodiment, the control data may be broadcasted to plural of the actuator cells simultaneously. The control circuits of the actuator cells may be configured to be responsive to a broadcasting, which addresses the control data associated with the broadcasting to plural of the actuator cells. Thereby, plural actuators may be actuated, e.g. simultaneously.

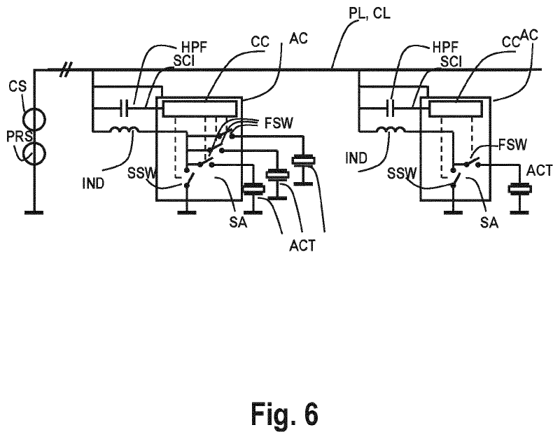

FIG. 4 depicts three actuator cells and FIGS. 5 and 6 each depict two actuator cells for illustrative purposes. In practice, hundreds, thousands or ten thousands of actuator cells may be comprised in the actuator array.

FIG. 5 depicts another embodiment of the actuator array according to the invention. The actuator array likewise comprises a power line PL and control line CL which are integral as a single, combined power and control line, connected to a plurality of actuator cells AC. The power line is powered by power supply PRS, a control system CS that transmits serial control signals to the actuator cells is connected in series with the power supply. Each actuator cell comprises an actuator ACT, a switch assembly SA and a control circuit CS to drive the switch assembly. In the present embodiment, the switching assembly comprises a switched mode converter. The switched mode converter is configured to convert the power line voltage at the power line into an actuator voltage to drive the actuator. In the present example, the switched mode converter comprises a step up converter, i.e. a boost converter formed by inductor L, first switch FSW and second switch SSW. The inductor is connected with a first inductor terminal thereof to the power line and with a second inductor terminal thereof to the second switch that connects between the second inductor terminal and ground. The second switch connects between the second inductor terminal and the actuator. The control circuit is connected to the first and second switches to control the switches into a conducting state respectively into a non-conducting state. For example, the control circuit operates the first and second switches at a boost converter switching frequency, whereby as the second switch is conducting, the inductor current is increased by the power line voltage over the inductor, while, as the second switch is driven to stop conducting, the inductor voltage at the second inductor terminal raises due to the inductive character of the inductor, and the first switch is driven into conductive state so as to connect the second inductor terminal to the actuator. Correspondingly, a step up converter is provided which is configured to provide an actuator voltage to the actuator which exceeds the power line voltage. As a result, high actuator voltage may be provided while keeping the power line voltage at a lower level. Setting a duty cycle of the switching of the first and second switches may enable to control the actuator voltage. Correspondingly, each actuator may be driven at a respective actuator voltage by the respective control circuit controlling a duty cycle of the respective first and second switches of the actuator cell. As another example of controlling the switches by the control circuit, in the absence of a resistive load, a stable output voltage (c.q. piezo charge) may be achieved as follows. Increasing output voltage may be achieved by closing the second switch SSW first. This charges the inductor to a current level and energy which depend on supply voltage, switch activation time and inductor value. Upon de-activation of the second switch SSW, the first switch FSW is closed which transfers the inductor energy into the load capacitor, comprised by the piezo (with or without its reference capacitor in series), thus increasing the load voltage. Decreasing output voltage may be performed by activation of the first switch FSW. With the output voltage larger than the supply voltage, this creates a backflow of energy from the load capacitor, i.e. the piezo electric actuator, thus decreasing its voltage by an amount that depends on the supply and load voltages, switch activation time and inductor value. Upon de-activation of the first switch FSW, the second switch SSW takes over the built-up inductor current and releases it into the supply without further affecting output voltage. Overall result may be that the load voltage can be controlled in quanta of energy, defined by the voltages and initial activation times of SSW for increasing output voltage and of FSW for decreasing output voltage. Moreover, when load voltage is required to be stable, no switches may need to be activated, which may avoid the dissipation of switching and conduction losses in the switch elements. Assuming change of output voltage may only occur sparsely in time, this may reduce the head load to the wafer and wafer table considerably.

As further depicted in FIG. 5, the control circuit is connected to the control line, in the present example the combined power line and control line, by a high pass filter HPF such as in the present example a capacitor, to enable to pass serial control data while blocking the direct current supply voltage at the combined power line and control line. The high pass filter is connected to the serial control input of the control circuit in order to enable to pass the serial control data to the serial control input.

The control circuit and the switching assembly may be comprised in an integrated circuit, such as an Application Specific Integrated Circuit, ASIC, or a Field Programmable Gate Array, FPGA, which may promote a compact implementation of each actuator cell.

In an embodiment the converter may be a bi-directional converter. When the control circuit drives the converter to raise the actuator voltage, electrical power is drawn by the bi-directional converter from the power line. When the control circuit drives the converter to lower the actuator voltage, electrical power is fed back by the bi-directional converter into the power line, thereby reducing a power consumption of the actuator array.

FIG. 6 depicts a further embodiment of the actuator array according to the invention. The actuator array likewise comprises a power line PL and control line CL which are integral as a single, combined power and control line, connected to a plurality of actuator cells AC, each actuator cell comprising an actuator ACT, a switch assembly SA and a control circuit CC to drive the switch assembly. In the present embodiment, the switching assembly comprises a switched mode converter. The switched mode converter is configured to convert the power line voltage at the power line into an actuator voltage to drive the actuator. In the present example, the switched mode converter comprises a step up converter, i.e. a boost converter formed by inductor L, plural first switches FSW and a second switch SSW. The inductor is connected with a first inductor terminal thereof to the power line and with a second inductor terminal thereof to the second switch that connect between the second inductor terminal and ground. The first switches connect between the second inductor terminal and respective actuators. As compared to the embodiment depicted in FIG. 5, the embodiment depicted in FIG. 6 may enable to drive plural actuators by a same control circuit.

For example, the control circuit operates the first and second switches at a boost converter switching frequency, whereby as the second switch is conducting, the inductor current is increased by the power line voltage over the inductor, while, as the second switch is driven to stop conducting, the inductor voltage at the second inductor terminal raises due to the inductive character of the inductor, and one of the first switch is driven into conductive state so as to connect the second inductor terminal to the respective actuator associated with the respective first switch. Correspondingly, a step up converter is provided which is configured to provide an actuator voltage to the actuator which exceeds the power line voltage. Switching at the boost converter switching frequency all of the first switches of the actuator cell simultaneously in a conductive state may enable to provide the same actuator voltage to all of the actuators of the actuator cell. Alternatively, the actuators of the actuator cell may be driven one by one, whereby the control circuit drives at the switching frequency the second switch and one of the first switches associated with one of the actuators to drive the corresponding actuator. As will be understood from the above description with reference to FIG. 5, the first and second switches are likewise to the embodiment described with reference to FIG. 5, driven in counter phase. Having driven the one actuator of the actuator cell for plural repetition time periods of the boost converter switching frequency, a desired actuator voltage may have been applied to the actuator, after which the control circuit may stop the switching of the one of the first switches. Accordingly, the first switches may be operated sequentially one by one to sequentially drive the respective actuators of the actuator cells one by one. For each one of the actuators, setting a duty cycle of the switching of the respective first switch and the second switch may enable to control the respective actuator voltage. Correspondingly, each actuator of the actuator cell may be driven at a respective actuator voltage by the control circuit controlling a duty cycle of the respective first switch, associated with the respective actuator, and the second switch of the actuator cell. As another example of controlling the switches by the control circuit, as described above with reference to FIG. 5, in the absence of a resistive load, a stable output voltage (c.q. piezo charge) may be achieved as follows. Increasing output voltage may be achieved by closing the second switch SSW first. This charges the inductor to a current level and energy which depend on supply voltage, switch activation time and inductor value. Upon de-activation of the second switch SSW, the first switch FSW is closed which transfers the inductor energy into the load capacitor, comprised by the piezo (with or without its reference capacitor in series), thus increasing the load voltage. Decreasing output voltage may be performed by activation of the first switch FSW. With the output voltage larger than the supply voltage, this creates a backflow of energy from the load capacitor, i.e. the piezo electric actuator, thus decreasing its voltage by an amount that depends on the supply and load voltages, switch activation time and inductor value. Upon de-activation of the first switch FSW, the second switch SSW takes over the built-up inductor current and releases it into the supply without further affecting output voltage. Overall result may be that the load voltage can be controlled in quanta of energy, defined by the voltages and initial activation times of SSW for increasing output voltage and of FSW for decreasing output voltage. Moreover, when load voltage is required to be stable, no switches may need to be activated, which may avoid the dissipation of switching and conduction losses in the switch elements. Assuming change of output voltage may only occur sparsely in time, this may reduce the head load to the wafer and wafer table considerably.

In order to drive the plural actuators of the one actuator cell individually, each at its actuator voltage, the control circuit of the actuator cell may be assigned plural addresses, e.g. a respective address per actuator. The addresses of the actuators may be stored in a memory of the control circuit. Accordingly, the actuator assembly may be configured to transmit via the control line the control data for the plural actuators of the control circuit by serial transmission to each one of the addresses of the actuators of the control circuit.

In the actuator array as described with reference to FIGS. 4, 5 and 6, the actuators may be piezo electric actuators having an intrinsic actuator capacitance. The actuator capacitance may be used as a holding circuit to hold an actuator voltage provided to the actuator. Thus, as the actuator has been driven by the operation of the switches of the switching assembly, the actuator may retain the actuator voltage until the actuator is driven again, by the actuator capacitance thereof. Accordingly, as the serial control via the serial control line may address the actuators of actuator cell in FIG. 6 one by one, the actuators may correspondingly be driven one by one, holding the actuator voltage until a next driving of the same actuator. A holding capacitance may be increased by providing a capacitor parallel to the actuator.

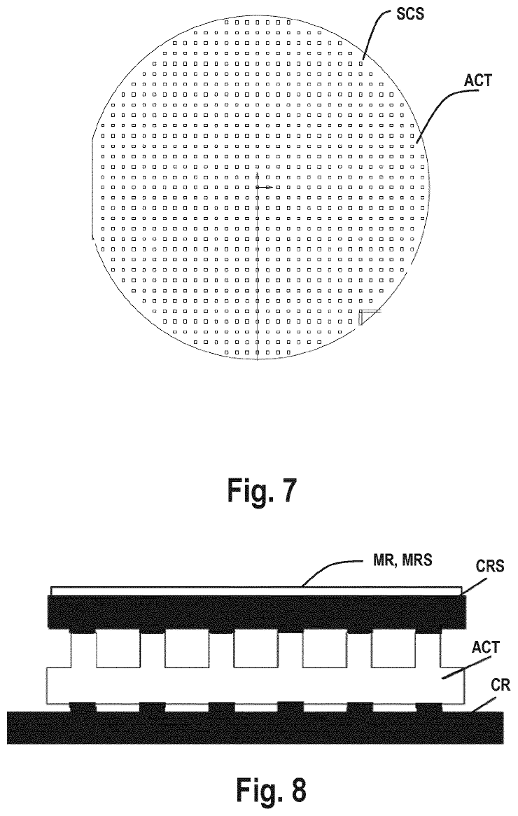

FIG. 7 depicts a top view of a plurality of actuators ACT as may be comprised in the actuator array according to the present invention. The actuators may be piezo electric actuators each configured to actuate a burl. Top surfaces of the burls may provide a substrate carrying surface. Power line and control line or the combined power line/control line may be provided as a plane substantially parallel to the substrate carrying surface, e.g. below the substrate carrying surface SCS so as to facilitate electrical connection of the actuator cells to the power line respectively control line. The actuators may for example be configured to actuate the burls in vertical direction, i.e. in Z direction, thus in a direction substantially perpendicular to the substrate carrying surface. The actuators may further be configured to actuate the burls in a direction parallel to the substrate carrying plane, e.g. in X direction or in Y direction, for example in combination with actuation in the Z direction. For example the actuators may be configured to actuate the burls in Z direction, in X direction, in Y direction, in Z direction and X direction, in Z direction and Y direction, in X direction and Y direction, or in Z direction, X direction and Y direction. In general terms, throughout the present document, the actuator(s) may be configured to actuate in vertical direction, i.e. in Z direction, in X direction or in Y direction. The X and Y directions define a substantially horizontal plane. In another embodiment, in general terms, throughout the present document, the actuator(s) may be configured to actuate in any combination of X, Y and Z directions, for example in Z direction, in X direction, in Y direction, in Z and X directions, in Z and Y directions, in Z, X and Y directions, or in X and Y directions.

According to an embodiment of the invention, a substrate table comprises a plurality of burls configured to support a substrate, the substrate table comprising an actuator array as described above, wherein the actuators of the actuator array are configured to actuate at least a subset of the burls. A lithographic apparatus may comprise the lithographic apparatus substrate table and/or the actuator array according to the invention.

In accordance with the invention, the actuators may be configured to actuate (i.e. move and/or generate a force) in any direction. For example, the actuators may be configured to actuate in a vertical direction. As another example, the actuators may be configured to actuate in a horizontal direction. As yet another example, the actuators may be configured to actuate in a horizontal and vertical directions, such as in x, y and z direction.

In the above example of the substrate table, the actuators may be configured to move the substrate in a vertical direction, in a horizontal direction, or in horizontal and vertical directions. For example, the actuators may be configured to actuate in 3 dimensions. By actuating the substrate in a horizontal direction, the actuators may position the substrate in a horizontal plane, which may assist to reduce overlay error in the lithographic apparatus.

The actuators may comprise any type of actuator. For example, in the case of piezo electric actuators, use may be made of sheer actuators to actuate in a horizontal direction. For example, the substrate table according to the invention which comprises a plurality of burls configured to support a substrate, the substrate table comprising an actuator array as described above, wherein the actuators of the actuator array are configured to actuate at least a subset of the burls in vertical and in horizontal direction. Actuating the burls in horizontal direction, e.g. making use of sheer pieze actuators, may enable to reduce overlay errors.

FIG. 8 depicts another embodiment, wherein a mirror MR comprising a mirror surface MRS, the mirror is provided with a plurality of actuators ACT that are arranged on a carrier CR and are configured to exert a force on a ceramic substrate CRS that may hold the mirror MR. The ceramic substrate CRS is arranged between the plurality of actuators and the mirror. The power line and control line or the combined power line/control line may be provided as a plane substantially parallel to the mirror surface, e.g. below the mirror surface so as to facilitate electrical connection of the actuator cells to the power line respectively control line. The mirror may be comprised in a projection system of a lithographic apparatus.

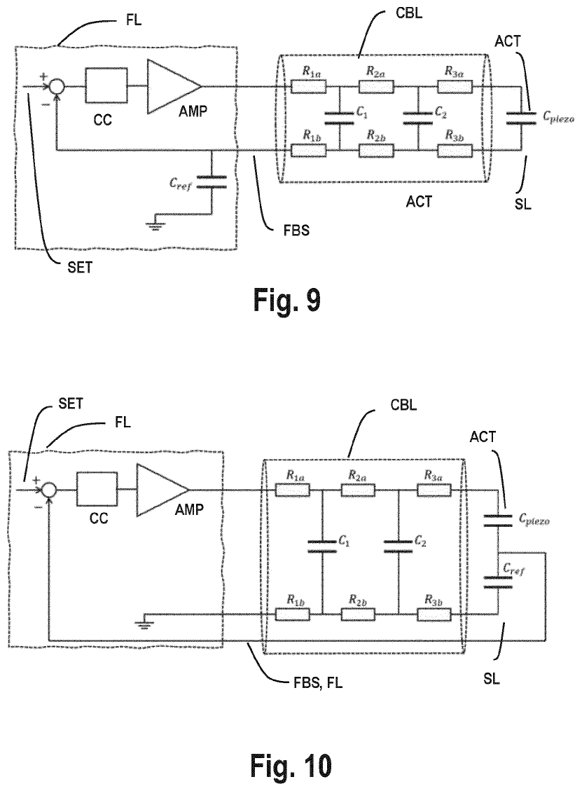

FIG. 9 depicts at least a part of an actuator cell comprising a piezo electric actuator ACT, having an electrical capacitance indicated by C_{piezo} and a driver to drive the actuator. The driver comprises a control circuit CC and an amplifier AMP which is driven by an output signal of the control circuit. A difference between an actuator setpoint signal SET and a feedback signal FBS is provided to the control circuit, an output of the control circuit is connected to the amplifier. The amplifier is configured to provide an actuator drive signal to the actuator. Thus, the control circuit and amplifier form a feedback loop to drive the actuator, responsive to the setpoint signal.

The actuator cell further comprises a reference capacitor C_{ref} which is in electrical series connection with the piezo electric actuator. As the reference capacitor and the piezo electric actuator form series connected electrical capacitances, an actuator drive current provided by the amplifier to the piezo electric actuator, also flows through the reference capacitor. As an electrical capacitance of the reference capacitor may be accurately known, a voltage across the reference capacitor may accurately reflect a charge held by the reference capacitor. As the reference capacitor and the piezo electric actuator are series connected and subject to a same actuator current, the charge held by the reference capacitor will reflect the charge held by the piezo electric actuator. In an embodiment, resistors are placed parallel to the actuator and the reference capacitor to obtain a defined low-frequent behavior. The resistors parallel to the actuator and to the reference capacitor may result in a cut-off frequency below which the charge amplifier actually behaves as a voltage amplifier, hence enabling to provide a defined and desired low frequency behaviour. For example, a low frequency voltage gain defined by the resistors is set to a same value as the higher frequency voltage gain defined by the capacitors, i.e. the capacitance of the actuator and the reference capacitor.

The piezo electric actuator may exhibit hysteresis, causing a non-linearity between the actuator drive signal and the excursion (position, force) of the piezo electric actuator. It has been observed that an extent of hysteresis may differ, depending on whether use is made of voltage drive, current drive of charge drive. More specifically, it has been observed that, in the case of charge drive, the hysteresis may be less compared to voltage drive. By means of the reference capacitor, a charge drive may be implemented, whereby the feedback signal provided to the controller is obtained from the voltage across the reference capacitor.

As depicted in FIG. 9, the actuator is arranged at a first location while the control circuit, amplifier, and reference capacitor are arranged at a second location remote from the first location. A cable, such as a coaxial cable, extends between the first and second locations to provide the actuator drive signal to one terminal of the actuator and to connect the other terminal of the actuator in a series connection with the reference capacitor. A parasitic capacitance between the conductors of the cable may extend along a length of the cable, and is symbolically indicated in FIG. 9 by C₁ and C₂ between the conductors. A series resistance of the conductors of the cable is symbolically indicated by R₁ₐ, R₂ₐ, R₃ₐ in one conductor and R_{1b}, R_{2b}, R_{3b} in the other conductor.

The configuration as described with reference to FIG. 9 may work satisfactorily, as long as the capacitances of the actuator and reference capacitor are large compared to the parasitic capacitance of the cable. In case the distance between the control circuit and the actuator, i.e. the distance between the first location and the second location increases, a cable capacitance may increase due to an increased cable length. Motion of the actuator may result in a change in parasitic capacitance of the cable, which may affect the charge control, in particular in case of a relatively large cable capacitance. Moreover, such large cable capacitance, parallel to the actuator, may affect the described charge control, as the larger the cable capacitance relative to the actuator capacitance the more of the charge will be absorbed by the cable, hence deviating from the charge control, which may increase hysteresis. The above effects may further be aggravated by a reduction of the actuator capacitance, e.g. due to smaller sized piezo electric actuators, causing a relative capacitance of the cable to be larger.

FIG. 10 depicts an embodiment of an actuator cell according to the invention, which actuator cell distinguishes from the actuator cell as depicted in and described with reference to FIG. 9, in that the reference capacitor is arranged at the first location, i.e. at the location of the actuator.

FIG. 10 depicts at least a part of an actuator cell comprising a piezo electric actuator ACT, having an electrical capacitance indicated by C_{piezo} and a driver to drive the actuator. The driver comprises a control circuit CC and an amplifier AMP which is driven by an output signal of the control circuit. A difference between an actuator setpoint signal SET and a feedback signal FBS is provided to the control circuit, an output of the control circuit is connected to the amplifier. The amplifier is configured to provide an actuator drive signal to the actuator. Thus, the control circuit and amplifier form a feedback loop to drive the actuator, responsive to the setpoint signal.

The actuator cell further comprises a reference capacitor C_{ref} which is in electrical series connection with the piezo electric actuator. As explained above, as the reference capacitor and the piezo electric actuator form series connected electrical capacitances, an actuator drive current provided by the amplifier to the piezo electric actuator, also flows through the reference capacitor. As an electrical capacitance of the reference capacitor may be accurately known, a voltage across the reference capacitor may accurately reflect a charge held by the reference capacitor. As the reference capacitor and the piezo electric actuator are series connected and subject to a same actuator current, the charge held by the reference capacitor will reflect the charge held by the piezo electric actuator. In an embodiment, resistors are placed parallel to the actuator and the reference capacitor to obtain a defined low-frequent behavior. The resistors parallel to the actuator and to the reference capacitor may result in a cut-off frequency below which the charge amplifier actually behaves as a voltage amplifier, hence enabling to provide a defined and desired low frequency behaviour. For example, a low frequency voltage gain defined by the resistors is set to a same value as the higher frequency voltage gain defined by the capacitors, i.e. the capacitance of the actuator and the reference capacitor. The resistors may be placed at the amplifier, i.e. at the second location and/or locally at the actuator and reference capacitor, i. e at the first location.

As depicted in FIG. 10, the actuator and reference capacitor are arranged at the first location while the control circuit and amplifier are arranged at the second location remote from the first location. The cable, such as the coaxial cable, extends between the first location and the second location. Via an actuator line of the cable, i.e. a conductor of the cable, the actuator drive signal is provided to one terminal of one of the actuator and the reference capacitor. The other terminal of one of the actuator or the reference capacitor is connected in a series connection with one terminal of the other one of the actuator and the reference capacitor. The other terminal of the other one of the actuator and the reference capacitor is connected via a return conductor of the cable, also referred to as a return line of the cable, to electrical ground. The feedback signal, representative of the voltage across the reference capacitor, is provided by a feedback line FL of the cable from the first location to the second location. Likewise to FIG. 9, the parasitic capacitance between the conductors of the cable may extend along the length of the cable, and is symbolically indicated in FIG. 10 by C₁ and C₂ between the conductors. The series resistance of the conductors of the cable is symbolically indicated by R₁ₐ, R₂ₐ, R₃ₐ in one conductor and R_{1b}, R_{2b}, R_{3b} in the other conductor.

In the embodiment depicted in FIG. 10, the terminal of the reference capacitor that is connected to the actuator, is connected to the feedback line, i.e. immediately provides the feedback signal to the control circuit. A sensitivity may arise, as the cable capacitance may influence the measurement of the charge held by the actuator, e.g via a cable capacitance of the feedback line of the cable, in a similar way as described above with reference to FIG. 9.

In the embodiment depicted in FIG. 11, the actuator cell further comprises a pre-amplifier PA, at the first location, which amplifies the reference capacitor voltage across the reference capacitor. A voltage gain of the pre-amplifier may be one or more than one, the pre-amplifier in fact buffers the reference capacitor voltage. The pre-amplifier may comprise high impedance pre-amplifier input. An output of the pre-amplifier is connected to the feedback line of the cable and provides the feedback signal to the control circuit. As a result of incorporation of the pre-amplifier, an influence of the cable on the feedback signal may at least be reduced. In an embodiment, resistors are placed parallel to the actuator and the reference capacitor to obtain a defined low-frequent behavior. The resistors parallel to the actuator and to the reference capacitor may result in a cut-off frequency below which the charge amplifier actually behaves as a voltage amplifier, hence enabling to provide a defined and desired low frequency behaviour. For example, a low frequency voltage gain defined by the resistors is set to a same value as the higher frequency voltage gain defined by the capacitors, i.e. the capacitance of the actuator and the reference capacitor. In the configuration in accordance with FIG. 11, the resistors may be placed at the actuator and the reference capacitor, respectively, i. e at the first location.

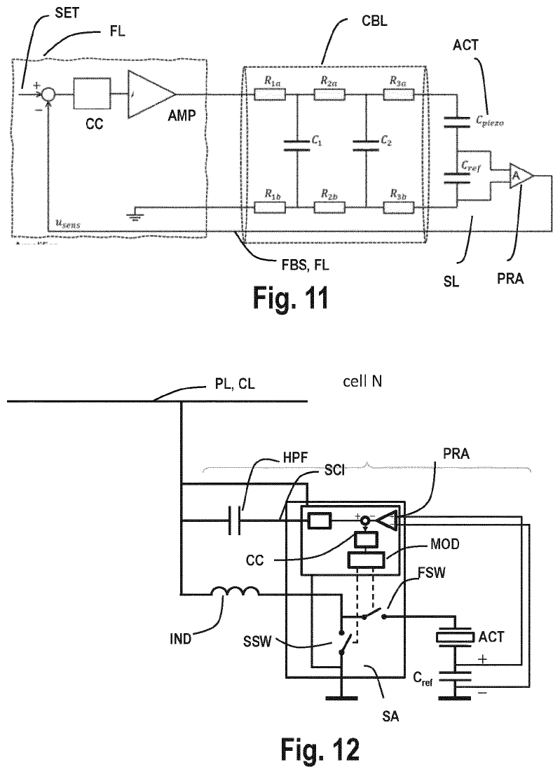

The charge control using the reference capacitor in series connection with the actuator and arranged proximate to the actuator, may also be employed in the embodiments as described above with reference to FIGS. 4-6 . An example is schematically depicted in FIG. 12 and will be explained with reference to FIG. 12. FIG. 12 depicts a highly schematic view of an actuator cell, similar to the actuator cells described above with reference to FIG. 5, provided with the reference capacitor and charge control as described above with reference to FIGS. 10 and 11. Accordingly, additionally to what has been described with reference to FIG. 5, the actuator cell further comprises the reference capacitor C_{ref} in series connection with the actuator ACT. The actuator (i.e. the piezo electric actuator) and the reference capacitor may be arranged at the first location while the control circuit and the switch assembly are arranged at the second location remote from the first location. As described with reference to FIG. 11, a pre-amplifier PRA may be used to buffer the reference capacitor voltage that forms the feedback signal. The control circuit CC may drive the switch assembly SA making use of the feedback signal representing a charge in the reference capacitor, hence a charge in the piezo electric actuator. The control circuit may derive a setpoint from the data obtained at the serial control input SCI. The actuator cell further comprises a modulator MOD electrically connected to the control circuit to be driven by the control circuit. The modulator is configured to drive the first and second switches of the switching assembly so as to charge respectively discharge the piezo electric actuator. Although in FIG. 12 the pre-amplifier has been drawn to be located proximate to the control circuit, the pre-amplifier may be located proximate to the actuator and the reference capacitor instead, i.e. may be located at the first location instead of at the second location. Adding the charge control in accordance with FIG. 12 to the embodiment as described with reference to FIGS. 4-6 , an accurate driving of the piezo electric actuators may be provided, as the described charge control may be less sensitive to actuator hysteresis, and as the arrangement of the reference capacitor proximate to the piezo electric actuator, i.e. both at the same end of the cable that interconnects the actuator and the control circuit, may reduce adverse effects of cable parasitics, such as cable capacitance, on the accuracy. In the embodiment in accordance with FIG. 12, similarly to the embodiments in accordance with FIGS. 4-6 , the cable length may be relatively small compared to the cable length in the embodiments of FIGS. 10 and 11. In other words, in the embodiment in accordance with FIG. 12, similarly to the embodiments in accordance with FIGS. 4-6 , the distance between the first and second locations may be relatively small compared to the distance between the first and second locations in the embodiments of FIGS. 10 and 11. In the embodiments as described with reference to FIGS. 4-6 and FIG. 12, the power line and control line may enable to distribute power and control data, enabling to position the control circuit and switches more closely to the actuators which may result in a more short cable to the actuator, i.e. a shorter distance between the first and second locations.

The present documents describes plural groups of embodiments, namely a first group of embodiments described with reference to FIG. 4-6 , a second group of embodiments described with reference to FIG. 9-10 and a third group of embodiments described with reference to FIG. 11. The actuator may be a piezo electric actuator. Unless specifically identifying the actuator as a piezo electric actuator, the actuator may be any other suitable actuator, such as any other capacitive actuator. The actuators in the first, second and third group of inventions may be the same or may differ from each other. Accordingly, the actuator in the first group of inventions may be identified as a first actuator, the actuator in the second group of inventions may be identified as a second actuator, the actuator in the third group of inventions may be identified as a third actuator.

The actuator cells in the first, second and third group of inventions may be the same or may differ from each other. Accordingly, the actuator cell in the first group of inventions may be identified as a first actuator cell, the actuator cell in the second group of inventions may be identified as a second actuator cell, the actuator cell in the third group of inventions may be identified as a third actuator cell.

The control circuits as described in the first, second and third group of inventions may be the same or may differ from each other. Accordingly, the control circuit in the first group of inventions may be identified as a first control circuit, the control circuit in the second group of inventions may be identified as a second control circuit, the control circuit in the third group of inventions may be identified as a third control circuit.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus.

Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Other aspects of the invention are set-out as in the following numbered clauses.
1. An actuator array, comprising:
multiple actuator cells, each actuator cell comprising
   at least one actuator,
   a switch assembly configured to switch power to the at least one actuator,
   a control circuit connected to the switch assembly and configured to control the switch assembly and comprising a serial control input,
a power line connected to at least the switch assembly of each actuator cell for powering at least the switch assembly of each actuator cell, and
a control line connected to the serial control input of the control circuit of each actuator cell to transmit control data to the control circuit of at least one of the actuator cells.
2. The actuator array according to clause 1, wherein the control line is integral with the power line and wherein each actuator cell comprises a high frequency pass filter connected between the power line and the serial control input.
3. The actuator array according to any one of the preceding clauses, wherein the switch assembly comprises a switched mode converter.
4. The actuator array according to clause 3, comprising plural actuators per actuator cell, wherein the switched mode converter comprises for each one of the plural actuators per actuator cell a respective first switch associated with the respective one of the plural actuators of the actuator cell.
5. The actuator array according to clause 4, wherein the control circuit is configured to operate the switched mode converter to sequentially power the plural actuators per actuator cell by sequentially operating in a conductive state the first switches associated with the respective ones of the plural actuators of the actuator cell.
6. The actuator array according to any one of clauses 3-5, wherein the switched mode converter comprises a bi-directional converter.
7. The actuator array according to any one of the preceding clauses, wherein the voltage line comprises an electrically conductive plane.
8. The actuator array according to any one of the preceding clauses, wherein each actuator comprises a piezo electric actuator.
9. The actuator array according to any one of the preceding clauses, wherein each of the control circuits is associated with a respective address and wherein the control circuits are configured to be individually addressable by addressing control data to the respective address via the control line.
10. The actuator array according to any one of the preceding clauses, wherein each of the control circuits is configured to be addressable by broadcasting control data via the control line.
11. The actuator array according to any one of the proceeding clauses, wherein the control circuit comprises one of an ASIC, a FPGA or a PCB.
12. The actuator array according to any one of the preceding clauses, further comprising a control transmitter configured to transmit via the control line serial control data to the actuator cells.
13. The actuator array according to any one of the preceding clauses, wherein the switch assembly comprises the switched mode converter which comprises
an inductor,
at least one first switch configured to electrically connect the inductor to the at least one actuator, and
a second switch configured and arranged to electrically connect the inductor between the power line and a ground,
wherein the control circuit is configured to alternatingly
operate the second switch in a conductive state to electrically connect the inductor between the power line and ground to enable an inductor electrical current to flow between the power line and ground and operate the first switch in a non-conductive state, and
operate the second switch in a non-conductive state and the first switch in a conductive state to electrically connect the inductor to the at least one actuator.
14. A substrate table comprising a plurality of burls configured to support a substrate, the substrate table comprising an actuator array according to any one of the preceding clauses, wherein the actuators of the actuator array are configured to actuate at least a subset of the burls.
15. The substrate table according to clause 14, wherein the control line is integral with the power line and extends as a plane substantially parallel to a substrate holding surface defined by the burls.
16. A lithographic apparatus comprising the substrate table according to clause 14 or 15.
17. A lithographic apparatus comprising the actuator array according to any one of clauses 1-13.
18. An actuator cell comprising
a piezo electric actuator,
a reference capacitor, in a series connection with the piezo electric actuator,
a control circuit configured to control the piezo electric actuator and the reference capacitor,
a feedback line configured to provide a reference capacitor voltage representative of a voltage across the reference capacitor to the control circuit,
wherein the piezo electric actuator and the reference capacitor are arranged at a first location and the control circuit is arranged at a second location, wherein the second location is remote from the first location and wherein the feedback line extends between the first location and the second location.
19. The actuator cell according to clause 18, wherein the actuator cell further comprises a pre-amplifier arranged at the first location and configured to amplify the voltage across the reference capacitor, a pre-amplifier output of the pre-amplifier being connected to the feedback line, the pre-amplifier being configured to output the amplified reference capacitor voltage onto the feedback line.
20. The actuator cell according to clause 18 or 19, wherein the actuator cell further comprises
a switch assembly configured to switch power to the series connection of the piezo electric actuator and the reference capacitor,
the control circuit being connected to the switch assembly and configured to control the switch assembly.
21. The actuator cell according to any one of clauses 18-20, wherein the actuator cell further comprises an amplifier configured to drive the series connection of the piezo electric actuator and the reference capacitor, wherein the control circuit is connected to the amplifier and configured to control the amplifier.
22. The actuator cell according to clause 19 or 21, further comprising a cable, electrically connected to the piezo electric actuator and the reference capacitor, the cable extending between the first location and the second location and comprising an actuator line connected to one of the actuator and the refence capacitor and a return line connected to the other one of the actuator and the reference capacitor.
23. A substrate table comprising a plurality of burls configured to support a substrate, the substrate table comprising an actuator cell according to any one of clauses 18-22, wherein the actuator of the actuator cell is configured to actuate at least one of the burls.
24. A lithographic apparatus comprising the substrate table according to clause 23.
25. A lithographic apparatus comprising the actuator cell according to any one of clauses 18-22.
26. An actuator array, comprising:
multiple actuator cells, each actuator cell comprising
   at least one piezo electric actuator,
   a reference capacitor, in a series connection with the piezo electric actuator,
   a switch assembly configured to switch power to the at least one actuator,
   a control circuit connected to the switch assembly and configured to control the switch assembly and comprising a serial control input,
   a feedback line configured to provide a reference capacitor voltage representative of a voltage across the reference capacitor to the control circuit,
wherein the piezo electric actuator and the reference capacitor are arranged at a first location and the control circuit is arranged at a second location, wherein the second location is remote from the first location and wherein the feedback line extends between the first location and the second location,
a power line connected to at least the switch assembly of each actuator cell for powering at least the switch assembly of each actuator cell, and
a control line connected to the serial control input of the control circuit of each actuator cell to transmit control data to the control circuit of at least one of the actuator cells.
27. The actuator array according to clause 26, wherein each actuator cell further comprises a pre-amplifier arranged at the first location and configured to amplify the voltage across the reference capacitor, a pre-amplifier output of the pre-amplifier being connected to the feedback line, the pre-amplifier being configured to output the amplified reference capacitor voltage onto the feedback line.
28. The actuator array according to clause 26 or 27, wherein each actuator cell further comprises a cable, electrically connected to the piezo electric actuator and the reference capacitor, the cable extending between the first location and the second location and comprising an actuator line connected to one of the actuator and the refence capacitor and a return line connected to the other one of the actuator and the reference capacitor.
29. The actuator array according to any one of clauses 26-28, wherein the control line is integral with the power line and wherein each actuator cell comprises a high frequency pass filter connected between the power line and the serial control input.
30. The actuator array according to any one of the preceding clauses 26 or 29, wherein the switch assembly comprises a switched mode converter.
31. The actuator array according to clause 30, comprising plural actuators per actuator cell, wherein the switched mode converter comprises for each one of the plural actuators per actuator cell a respective first switch associated with the respective one of the plural actuators of the actuator cell.
32. The actuator array according to clause 31, wherein the control circuit is configured to operate the switched mode converter to sequentially power the plural actuators per actuator cell by sequentially operating in a conductive state the first switches associated with the respective ones of the plural actuators of the actuator cell.
33. The actuator array according to any one of clauses 26-32, wherein the switched mode converter comprises a bi-directional converter.
34. The actuator array according to any one of the preceding clauses 26-33, wherein the voltage line comprises an electrically conductive plane.
35. The actuator array according to any one of the preceding clauses 26-34, wherein each actuator comprises a piezo electric actuator.
36. The actuator array according to any one of the preceding clauses 26-35, wherein each of the control circuits is associated with a respective address and wherein the control circuits are configured to be individually addressable by addressing control data to the respective address via the control line.
37. The actuator array according to any one of the preceding clauses 26-36, wherein each of the control circuits is configured to be addressable by broadcasting control data via the control line.
38. The actuator array according to any one of the proceeding clauses 26-37, wherein the control circuit comprises one of an ASIC, a FPGA or a PCB.
39. The actuator array according to any one of the preceding clauses 26-38, further comprising a control transmitter configured to transmit via the control line serial control data to the actuator cells.
40. The actuator array according to any one of the preceding clauses 26-39, wherein the switch assembly comprises the switched mode converter which comprises
an inductor,
at least one first switch configured to electrically connect the inductor to the at least one actuator, and
a second switch configured and arranged to electrically connect the inductor between the power line and a ground,
wherein the control circuit is configured to alternatingly
operate the second switch in a conductive state to electrically connect the inductor between the power line and ground to enable an inductor electrical current to flow between the power line and ground and operate the first switch in a non-conductive state, and
operate the second switch in a non-conductive state and the first switch in a conductive state to electrically connect the inductor to the at least one actuator.
41. A substrate table comprising a plurality of burls configured to support a substrate, the substrate table comprising an actuator array according to any one of the preceding clauses 26-40, wherein the actuators of the actuator array are configured to actuate at least a subset of the burls.
42. The substrate table according to clause 41, wherein the control line is integral with the power line and extends as a plane substantially parallel to a substrate holding surface defined by the burls.
43. A lithographic apparatus comprising the substrate table according to clause 41 or 42.
44. A lithographic apparatus comprising the actuator array according to any one of clauses 26-40.

1.-15. (canceled)

16. An actuator array, comprising:
multiple actuator cells, each actuator cell comprising
at least one piezo electric actuator,
a reference capacitor, in a series connection with the piezo electric actuator,
a switch assembly configured to switch power to the at least one actuator,
a control circuit connected to the switch assembly and configured to control the switch assembly and comprising a serial control input, and
a feedback line configured to provide a reference capacitor voltage representative of a voltage across the reference capacitor to the control circuit,
wherein the piezo electric actuator and the reference capacitor are arranged at a first location and the control circuit is arranged at a second location, wherein the second location is remote from the first location and wherein the feedback line extends between the first location and the second location;
a power line connected to at least the switch assembly of each actuator cell to power at least the switch assembly of each actuator cell; and
a control line connected to the serial control input of the control circuit of each actuator cell to transmit control data to the control circuit of at least one of the actuator cells.

17. The actuator array of claim 16, wherein each actuator cell further comprises a pre-amplifier arranged at the first location and configured to amplify the voltage across the reference capacitor, a pre-amplifier output of the pre-amplifier being connected to the feedback line, the pre-amplifier being configured to output the amplified reference capacitor voltage onto the feedback line.

18. The actuator array of claim 16, wherein each actuator cell further comprises a cable, electrically connected to the piezo electric actuator and the reference capacitor, the cable extending between the first location and the second location and comprising an actuator line connected to one of the actuator and the reference capacitor and a return line connected to the other one of the actuator and the reference capacitor.

19. The actuator array of claim 16, wherein the control line is integral with the power line and wherein each actuator cell comprises a high frequency pass filter connected between the power line and the serial control input.

20. The actuator array of claim 16, wherein the switch assembly comprises a switched mode converter.

21. The actuator array of claim 20, comprising plural actuators per actuator cell, wherein the switched mode converter comprises for each one of the plural actuators per actuator cell a respective first switch associated with the respective one of the plural actuators of the actuator cell.

22. The actuator array of claim 21, wherein the control circuit is configured to operate the switched mode converter to sequentially power the plural actuators per actuator cell by sequentially operating in a conductive state the first switches associated with the respective ones of the plural actuators of the actuator cell.

23. The actuator array of claim 16, wherein the switched mode converter comprises a bi-directional converter.

24. The actuator array of claim 16, wherein the voltage line comprises an electrically conductive plane.

25. The actuator array of claim 16, wherein each actuator comprises a piezo electric actuator.

26. The actuator array of claim 16, wherein each of the control circuits is associated with a respective address and wherein the control circuits are configured to be individually addressable by addressing control data to the respective address via the control line.

27. The actuator array of claim 16, wherein each of the control circuits is configured to be addressable by broadcasting control data via the control line.

28. The actuator array of claim 16, wherein the control circuit comprises one of an ASIC, a FPGA or a PCB.

29. The actuator array of claim 16, further comprising a control transmitter configured to transmit via the control line serial control data to the actuator cells.

30. The actuator array of claim 16, wherein the switch assembly comprises the switched mode converter that comprises:
an inductor,
at least one first switch configured to electrically connect the inductor to the at least one actuator, and
a second switch configured and arranged to electrically connect the inductor between the power line and a ground,
wherein the control circuit is configured to alternatingly
operate the second switch in a conductive state to electrically connect the inductor between the power line and ground to enable an inductor electrical current to flow between the power line and ground and operate the first switch in a non-conductive state, and
operate the second switch in a non-conductive state and the first switch in a conductive state to electrically connect the inductor to the at least one actuator.

31. A substrate table comprising a plurality of burls configured to support a substrate, the substrate table comprising the actuator array of claim 16, wherein the actuators of the actuator array are configured to actuate at least a subset of the burls.

32. The substrate table of claim 31, wherein the control line is integral with the power line and extends as a plane substantially parallel to a substrate holding surface defined by the burls.

33. A lithographic tool comprising the substrate table of claim 31.

34. A lithographic tool comprising the actuator array of claim 16.
